(19) United States
(12) Patent Application Publication
(10) Pub. No.: US 2026/0024247 A1
(43) Pub. Date: Jan. 22, 2026

(54) ARTIFICIAL INTELLIGENCE BASED METHOD FOR PRESENTING DATA RELATED TO DEFECTS DISCOVERED BY AN INSPECTION SYSTEM

(71) Applicant: Applied Materials Israel Ltd., Rehovot (IL)

(72) Inventors: Ortal YESODI, Modiin-Maccabim-Reut (IL); Yuval ALFASSI, Rehovot (IL); Marcelo BACHER, Givatayim (IL)

(21) Appl. No.: 18/774,820

(22) Filed: Jul. 16, 2024

(51) Int. Cl. G06T 11/20; G06T 7/00

(52) U.S. Cl. CPC G06T 11/206; G06T 7/0004; G06T 2207/20084; G06T 2207/30148

(57) ABSTRACT

A method of presenting defects data produced by inspection of semiconductor wafers or masks, the method including receiving defect data including a plurality of attributes per defect, using t-distributed Stochastic Neighbor Embedding to embed the defects attributes from a multi-dimensional attribute space into a lower-dimension space, and displaying the defect data embedded into the lower-dimension space on a 2D display as a scatter plot. A system for inspecting wafers or masks, the system including a user interface for presenting defect data produced by inspection of wafers or masks, the user interface implementing a method including receiving defect data including a plurality of attributes per defect, using t-distributed Stochastic Neighbor Embedding to embed the defects attributes from a multi-dimensional attribute space into a lower-dimension space, and displaying the defects data embedded into the lower-dimension space on a 2D display as a scatter plot. Related apparatus and methods are also described.

### TECHNOLOGICAL FIELD

The present disclosure, in some embodiments thereof, relates to a user interface for presenting defect data produced by inspection of wafers or masks.

### BACKGROUND

The semiconductor industry presently uses inspection systems which scan wafers and/or masks at a very high definition on the order of a few nanometers. The scans produce images of a current scanning window, which are compared to other images of other scanning windows of a similar structure in an area of the wafer and/or mask which is presumed to contain no defect. If the comparison shows a significant difference between the images, the current scanning window is suspected of having imaged a defect.

### OVERVIEW

Inspection scanning can produce many images suspected of containing defects. The many suspected defect images can further be handled by analysis and computerized tools to provide actionable feedback to a manufacturer of the wafers or masks.

In some examples, suspected defect images are discovered by comparing images similar regions of a wafer or a mask to each other. If the difference between the similar images is considered to be significant, one of the images is considered to be an image which is suspected to include a defect. In some cases, a difference image is produced, the difference image being a matrix subtraction of the similar image matrices one from another. Typically, one image is termed a reference image, and is known not to include a defect, or almost certainly known not to include a defect, and one image is termed a current image, and is the image which is being scanned for defects. A significant difference between the reference image and the current image typically causes the current image to be suspected of including a defect.

The present disclosure, in some embodiments thereof, relates to a user interface for presenting defect data produced by inspection of wafers or masks. The user interface includes one or more of:
tools for selecting various aspects of machine learning to be used for defect classification;
tools for categorization of defects—whether one at a time or in groups or in categories as classified by a machine-learning program;
tools for display of defect images;
tools for performing actions to change or enhance image defects; and
tools for selecting how to present one or more two-dimensional (2D) scatter plot(s) for displaying defects based on two of their several attributes.

### Defect Attributes

Deciding when a difference between two images is significant may be decided based on various attributes of the difference. In some case the attributes for deciding what is a candidate defect image may be selected by a user-some non-limiting examples being: a size of an area in which there is a difference being greater than some area threshold; a difference in amplitude or brightness of a number of pixels being greater than some amplitude threshold; a specific shape of a difference such as round, square, rectangular, linear, eccentricity greater than some threshold; and other such criteria which are recognized as being typical of defects. In some cases, candidate defect images are determined based on identifying “killer” defects which may make an associated electronic circuit malfunction.

When a candidate defect image is determined, attributes of one or more of the current image, the reference image, and the difference image are optionally collected, and termed herein image attributes of the candidate defect image. Some example attributes include one or more of segmentation information associated with any one of the images, CAD information for producing an imaged area, information related to the difference image, measurement information related to any one of the images, and additional attributes described elsewhere herein. In addition, non-image attributes may also be collected, as described further below.

### Assigning Attributes to a Defect Image by Machine Learning

Deciding when a difference between two images is significant may be performed by training an analysis module by machine learning on defect images, or on difference images, feeding the machine learning process images which are already categorized as defective, and optionally images categorized as not defective. In such cases the machine learning learns to classify images as defective or not, without a user instructing the machine learning what to look for and how to identify defects. In some cases, the machine learning training is performed by supervised training.

In some cases, the machine learning process images which are already categorized as defective may include a category or class of the defects. In such cases the machine learning may learn to classify images as belonging to a specific defect category or class.

The many suspected defect images may be automatically classified into defect categories based on sharing similar defect attributes. In some cases, a machine learning module is used to classify the suspected defects into categories of defects, optionally based on attributes discovered by the machine learning module. In some cases, a user may select one or more suspected defects from a cluster of suspect defects, view the suspected defects, and categorize one or more of the defects viewed, optionally neighboring defects, and optionally the entire cluster, as belonging to a specific category of defect.

### Optionally Assigning Non-Image Attributes to a Defect

In some cases, suspected defect images optionally have additional attributes assigned to them, such as, by way of some non-limiting one or more of:
identification of a machine used to produce the wafer or mask;
identification of an inspection machine used to image the wafer or mask;
identification of a production process used to produce the wafer or mask;
date of a production step;
time of a production step;
shift of a production step;
operator performing a production step; and
additional attributes which can connect production of a defect to what/who/when the defect was produced.

The attributes termed “additional” in the list above can potentially indicate a source of the defects.

### Defect Categories

Defects in a wafer or a mask fall into categories. Image attributes can correlate to defect categories. For example, defect images, or Diff images, of a same defect category will usually have similar image attributes, and can typically be categorized together.

In some examples the categorization may be done automatically by machine learning, which associates defect candidates with their corresponding defect category. In some examples the categorization may be done by a human operator viewing a defect image. The categorization may be done automatically by grouping together candidate defects that are close to each other in an attribute space.

### 2D Scatter Plots

Now that a number of candidate defect images have been collected, and defect image attributes have been associated with the candidate defect images, it is noted that typically the number of candidate defect images is very great. The number of candidate defect images is often larger than a number which can typically be analyzed by a human operator during an appropriate time frame.

In some examples, the attributes are considered as an attribute space, with each attribute being considered one axis in a multi-dimensional attribute space.

In some examples, a user may manually select which two attributes will be used for the two axes.

In some examples, a user may define that only image attributes will be used for the two axes, and not the “additional” attributes listed above.

In some examples, a mathematical dimensionality reduction technique is used for selecting the two axes.

In some examples, the mathematical dimensionality reduction technique includes a technique named, t-distributed Stochastic Neighbor Embedding (t-SNE). t-SNE is an unsupervised non-linear dimensionality reduction technique for data exploration and visualizing high-dimensional data.

In some examples, the mathematical dimensionality reduction technique includes non-linear techniques such as, by way of some non-limiting examples: Auto Encoders (AEs), Variational Autoencoders (VAE) and Kernel PCA.

In some examples, the mathematical dimensionality reduction technique includes linear techniques such as, by way of some non-limiting examples: Principal Component Analysis (PCA), Factor Analysis (FA), Linear Discriminant Analysis (LDA) and Non-Negative Matrix Factorization (NMF).

### 3D Scatter Plots

In some examples, three attributes are optionally selected, manually or automatically, and a three-dimensional (3D) scatter plot is produced, similarly to the production of 2D scatter plots described above.

A mathematical dimensionality reduction technique is optionally used for selecting three axes.

Any one of the mathematical dimensionality reduction techniques described with reference to two dimensions and two axes, may be used to produce 3D scatter plots.

In some examples a 3D scatter plot may be displayed, using any method known for displaying such scatter plots, by way of a non-limiting example by displaying a perspective view from any user-selected or automatically selected direction relative to a 3D volume of the 3D scatter plot.

Displaying Data from Multiple Wafers or Dies in One Image or Scatter Plot

In some examples defect data or images from several wafers, registered to a same coordinate system, may be displayed and analyzed together, in one scatter plot or wafer map. Such displaying potentially assists analysis of location dependent defects.

In some examples data from a specific die on a wafer, from several wafers, registered to a same coordinate system, may be displayed and analyzed together. Such display potentially enables to detect and analyze location-dependent defect at a die level.

### BRIEF DESCRIPTION OF THE DRAWINGS

Some embodiments of the disclosure are herein described, by way of example only, with reference to the accompanying drawings. With specific reference now to the drawings in detail, it is stressed that the particulars shown are by way of example and for purposes of illustrative discussion of embodiments of the disclosure. In this regard, the description taken with the drawings makes apparent to those skilled in the art how embodiments of the disclosure may be practiced.

In the drawings:

FIG. 1A is a simplified block diagram of an examination system according to an example;

FIG. 1B is a simplified illustration of a process of producing a difference image, also call a Diff image, and assigning attributes to the Diff image according to an example;

FIG. 2A is a simplified illustration of a user interface according to an example;

FIG. 2B is a simplified illustration of a user interface according to an example;

FIG. 3A is a simplified illustration of a user interface according to an example;

FIG. 3B is a simplified illustration of a user interface according to an example;

FIG. 3C is a simplified illustration of a user interface according to an example;

FIG. 4A is a simplified illustration of a user interface according to an example;

FIG. 4B is a simplified illustration of a user interface according to an example;

FIG. 4C is a simplified illustration of a user interface according to an example;

FIG. 4D is a simplified illustration of three-dimensional (3D) scatter plots according to an example;

FIG. 5 is a simplified illustration of a user interface element according to an example; and

FIG. 6 is a simplified flow chart illustration of a method of presenting defects data produced by inspection of wafers or masks according to an example.

### DETAILED DESCRIPTION OF EXAMPLES

The present disclosure, in some embodiments thereof, relates to a user interface for presenting defect data produced by inspection of wafers or masks.

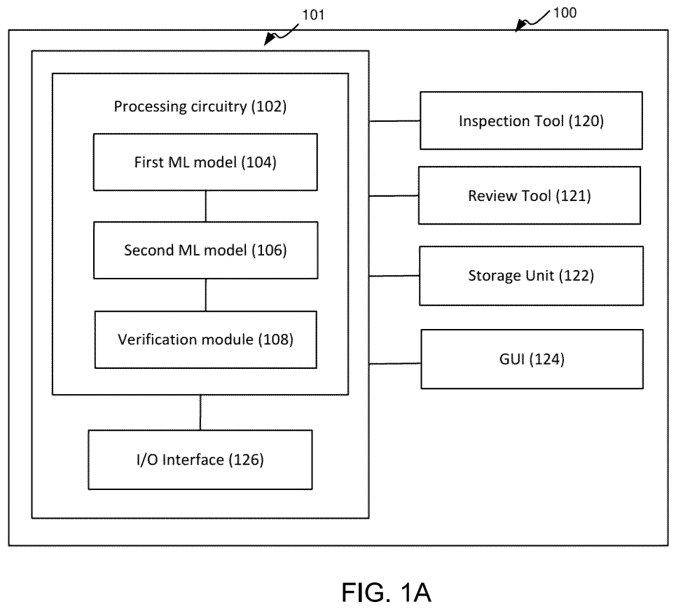

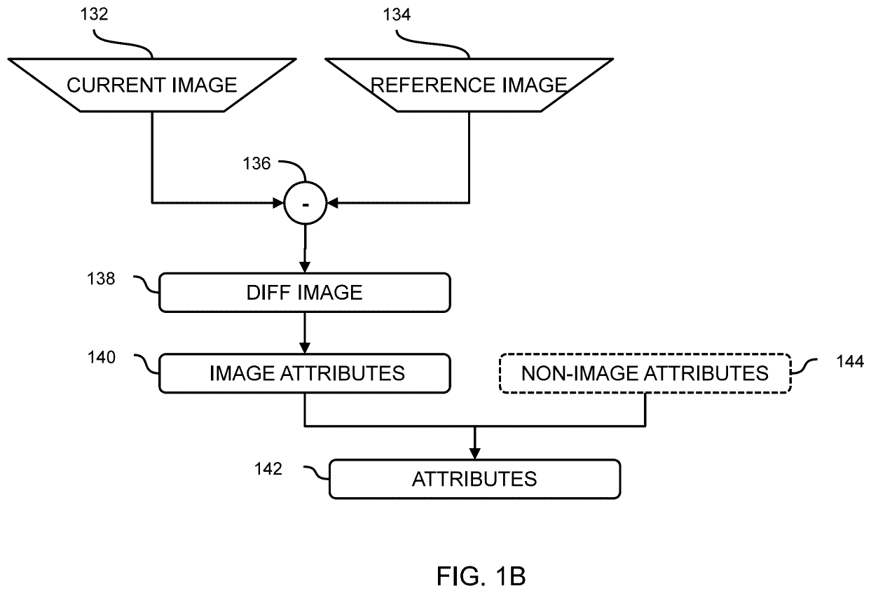

Reference is now made to FIG. 1A, which is a simplified block diagram of an examination system according to an example.

The examination system 100 illustrated in FIG. 1A can be used for examination of a semiconductor specimen (e.g., a wafer, a die, or parts thereof) as part of the specimen fabrication process. As described above, the examination referred to herein can be construed to cover any kind of operations related to defect inspection/detection, defect review, defect classification, nuisance filtration, segmentation, and/or metrology operations, such as, e.g., critical dimension (CD) measurements, etc., with respect to the specimen. System 100 comprises one or more examination tools configured to scan a specimen and capture images thereof to be further processed for various examination applications.

The term “examination tool(s)” used herein should be expansively construed to cover any tools that can be used in examination-related processes, including, by way of non-limiting example, scanning (in a single or in multiple scans), imaging, sampling, reviewing, measuring, classifying, and/or other processes provided with regard to the specimen or parts thereof. Without limiting the scope of the disclosure in any way, it should also be noted that the examination tools can be implemented as inspection machines of various types, such as optical inspection machines, electron beam inspection machines (e.g., a Scanning Electron Microscope (SEM), an Atomic Force Microscopy (AFM), or a Transmission Electron Microscope (TEM), etc.), and so on.

The one or more examination tools can include one or more inspection tools 120 and one or more review tools 121. In some cases, an inspection tool 120 can be configured to scan a specimen (e.g., an entire wafer, an entire die, or portions thereof) to capture inspection images (typically, at a relatively high-speed and/or low-resolution) for detection of potential defects (i.e., defect candidates). During inspection, the wafer can move at a step size relative to the detector of the inspection tool (or the wafer and the tool can move in opposite directions relative to each other) during the exposure, and the wafer can be scanned step-by-step along swaths of the wafer by the inspection tool, where the inspection tool images a part/portion (within a swath) of the specimen at a time. By way of example, the inspection tool can be an optical inspection tool. At each step, light can be detected from a rectangular portion of the wafer and such detected light is converted into multiple intensity values at multiple points in the portion, thereby forming an image corresponding to the part/portion of the wafer. For instance, in optical inspection, an array of parallel laser beams can scan the surface of a wafer along the swaths. The swaths are laid down in parallel rows/columns contiguous to one another, to build up, swath-at-a-time, an image of the surface of the wafer. For instance, the tool can scan a wafer along a swath from up to down, then switch to the next swath and scan it from down to up, and so on and so forth, until the entire wafer is scanned and inspection images of the wafer are collected.

In some cases, a review tool 121 can be configured to capture review images of at least some of the defect candidates detected by inspection tools for ascertaining whether a defect candidate is indeed a defect of interest (DOI). Such a review tool is usually configured to inspect fragments of a specimen, one at a time (typically, at a relatively low-speed and/or high-resolution). By way of example, the review tool can be an electron beam tool, such as, e.g., a scanning electron microscope (SEM), etc. An SEM is a type of electron microscope that produces images of a specimen by scanning the specimen with a focused beam of electrons. The electrons interact with atoms in the specimen, producing various signals that contain information on the surface topography and/or composition of the specimen. An SEM is capable of accurately inspecting and measuring features during the manufacture of semiconductor wafers.

The inspection tool 120 and review tool 121 can be different tools located at the same or at different locations, or a single tool operated in two different modes. In some cases, the same examination tool can provide low-resolution image data and high-resolution image data. The resulting image data (low-resolution image data and/or high-resolution image data) can be transmitted—directly or via one or more intermediate systems—to system 101. The present disclosure is not limited to any specific type of examination tools and/or the resolution of image data resulting from the examination tools. In some cases, at least one of the examination tools has metrology capabilities and can be configured to capture images and perform metrology operations on the captured images. Such an examination tool is also referred to as a metrology tool.

According to certain embodiments of the presently disclosed subject matter, the examination system 100 comprises a computer-based system 101 operatively connected to the inspection tool 120 and the review tool 121, and is capable of automatically monitoring/verifying quality of synthetic images generated by ML based image reconstruction techniques. System 101 is also referred to as an image reconstruction monitoring system, or verification system.

System 101 includes a processing circuitry 102 operatively connected to a hardware-based I/O interface 126 and configured to provide processing necessary for operating the system. The processing circuitry 102 can comprise one or more processors (not shown separately) and one or more memories (not shown separately). The one or more processors of the processing circuitry 102 can be configured to, either separately or in any appropriate combination, execute several functional modules in accordance with computer-readable instructions implemented on a non-transitory computer-readable memory comprised in the processing circuitry. Such functional modules are referred to hereinafter as comprised in the processing circuitry.

According to certain embodiments, one or more functional modules comprised in the processing circuitry 102 of system 101 can include a first ML model 104, a second ML model 106, and a verification module 108 operatively connected to each other. The first ML model 104 and the second ML model 106 may be previously trained during a training/setup phase.

Specifically, the processing circuitry 102 can be configured to obtain, via an I/O interface 126, an input image of a semiconductor specimen, and process the input image using the first ML model 104, to obtain a synthetic image corresponding to the input image. The first ML model may be previously trained for image reconstruction for a specific application. The synthetic image may be reconstructed to resemble a target image pertaining to the specific application.

The processing circuitry 102 can be configured to process, by the second ML model 106, the synthetic image and one of the input image or a target image of the synthetic image, to obtain a defect map indicative of defect distribution in the input image or the target image with respect to the synthetic image. The second ML model may be previously trained for defect detection. The verification module 108 can be configured to verify quality of the synthetic image based on the defect map.

In some cases, the first ML model 104, the second ML model 106 and the verification module 108 can be regarded as part of an examination recipe usable for performing runtime examination operations for semiconductor specimens, including defect detection/review, image enhancement, image simulation, etc., on various input images, such as acquired runtime images and design images of a specimen.

In some embodiments, system 101 can be configured as a training system capable of training the first ML model 104 and/or the second ML model 106 during a training/setup phase. In such cases, one or more functional modules comprised in the processing circuitry 102 of system 101 can include a training module (not illustrated in the figure), and the first ML model 104 and the second ML model 106 to be trained (i.e., models that are not yet trained). Specifically, the training module can be configured to obtain a respective training set, and use the training set to train the first or the second model, as will be detailed below.

According to certain embodiments, the first ML model and/or the second ML model can be implemented as various types of machine learning models, such as, e.g., decision tree, Support Vector Machine (SVM), Artificial Neural Network (ANN), regression model, Bayesian network, or ensembles/combinations thereof etc. The learning algorithms used by the ML models can be any of the following: supervised learning, unsupervised learning, self-supervised, semi-supervised learning, or a combination thereof, etc. The presently disclosed subject matter is not limited to the specific types of the ML models or the specific types of learning algorithms used by the ML models.

By way of example, in some cases, the ML models can be implemented as a deep neural network (DNN). DNN can comprise multiple layers organized in accordance with respective DNN architecture. By way of non-limiting example, the layers of DNN can be organized in accordance with architecture of a Convolutional Neural Network (CNN), Recurrent Neural Network, Recursive Neural Networks, autoencoder, Generative Adversarial Network (GAN), or otherwise. Optionally, at least some of the layers can be organized into a plurality of DNN sub-networks. Each layer of DNN can include multiple basic computational elements (CE), typically referred to in the art as dimensions, neurons, or nodes.

The weighting and/or threshold values associated with the CEs of a DNN and the connections thereof can be initially selected prior to training, and can be further iteratively adjusted or modified during training to achieve an optimal set of weighting and/or threshold values in a trained DNN. After each iteration, a difference can be determined between the actual output produced by DNN module and the target output associated with the respective training set of data. The difference can be referred to as an error value. Training can be determined to be complete when a loss/cost function indicative of the error value is less than a predetermined value, or when a limited change in performance between iterations is achieved. A set of input data used to adjust the weights/thresholds of a DNN is referred to as a training set.

It is noted that the teachings of the presently disclosed subject matter are not bound by specific architecture of the ML models as described above.

It is to be noted that while certain embodiments of the present disclosure refer to the processing circuitry 102 being configured to perform the above recited operations, the functionalities/operations of the aforementioned functional modules can be performed by the one or more processors in processing circuitry 102 in various ways. By way of example, the operations of each functional module can be performed by a specific processor, or by a combination of processors. The operations of the various functional modules, such as the ML model processing, and quality verification, etc., can thus be performed by respective processors (or processor combinations) in the processing circuitry 102, while, optionally, these operations may be performed by the same processor. The present disclosure should not be limited to being construed as one single processor always performing all the operations.

In some cases, additionally to system 101, the examination system 100 can comprise one or more examination modules, such as, e.g., defect detection module, nuisance filtration module, Automatic Defect Review Module (ADR), Automatic Defect Classification Module (ADC), metrology operation module, and/or other examination modules which are usable for examination of a semiconductor specimen. The one or more examination modules can be implemented as stand-alone computers, or their functionalities (or at least part thereof) can be integrated with the inspection and tool 120 and review tool 121. In some cases, the output of system 101, e.g., the verification result, and the verified synthetic images, can be provided to the one or more examination modules (such as the ADR, ADC, etc.) for further processing. In some cases, the functional modules 104, 106, and 108 can be comprised in the one or more examination modules for purpose of image reconstruction and verification. Optionally, these functional modules can be shared between the examination modules or, alternatively, each of the one or more examination modules can comprise its own functional modules.

According to certain embodiments, system 100 can comprise a storage unit 122. The storage unit 122 can be configured to store any data necessary for operating system 101, e.g., data related to input and output of system 101, as well as intermediate processing results generated by system 101. By way of example, the storage unit 122 can be configured to store images of the specimen and/or derivatives thereof produced by the inspection tool 120, such as, e.g., the input images, synthetic images, and the training set, as described above. Accordingly, the different types of input data as required can be retrieved from the storage unit 122 and provided to the processing circuitry 102 for further processing. The output of the system 101, such as, e.g., the verification result, the verified synthetic images, etc., can be sent to storage unit 122 to be stored.

In some embodiments, system 100 can optionally comprise a computer-based Graphical User Interface (GUI) 124 which is configured to enable user-specified inputs related to system 101. For instance, the user can be presented with a visual representation of the specimen (for example, by a display forming part of GUI 124), including the images of the specimen, the defect maps, etc. The user may be provided, through the GUI, with options of defining certain operation parameters. The user may also view the operation results or intermediate processing results, such as, e.g., the verification result, and the verified synthetic images, etc., on the GUI.

In some cases, system 101 can be further configured to send, via I/O interface 126, the operation results to the examination tools 120 and 121 for further processing. In some cases, system 101 can be further configured to send the results to the storage unit 122, and/or external systems (e.g., Yield Management System (YMS) of a fabrication plant (fab)). A yield management system (YMS) in the context of semiconductor manufacturing is a data management, analysis, and tool system that collects data from the fab, especially during manufacturing ramp ups, and helps engineers find ways to improve yield. A YMS helps semiconductor manufacturers and fabs manage high volumes of production analysis with fewer engineers. These systems analyze the yield data and generate reports. A YMS can be used by Integrated Device Manufacturers (IMD), fabs, fabless semiconductor companies, and Outsourced Semiconductor Assembly and Test (OSAT).

Those versed in the art will readily appreciate that the teachings of the presently disclosed subject matter are not bound by the system illustrated in FIG. 1A. Each system component and module in FIG. 1A can be made up of any combination of software, hardware, and/or firmware, as relevant, executed on a suitable device or devices, which perform the functions as defined and explained herein. Equivalent and/or modified functionality, as described with respect to each system component and module, can be consolidated or divided in another manner. Thus, in some embodiments of the presently disclosed subject matter, the system may include fewer, more, modified and/or different components, modules, and functions than those shown in FIG. 1A.

Each component in FIG. 1A may represent a plurality of the particular components, which are adapted to independently and/or cooperatively operate to process various data and electrical inputs, and for enabling operations related to a computerized examination system. In some cases, multiple instances of a component may be utilized for reasons of performance, redundancy, and/or availability. Similarly, in some cases, multiple instances of a component may be utilized for reasons of functionality or application. For example, different portions of the particular functionality may be placed in different instances of the component.

It should be noted that the examination system illustrated in FIG. 1A can be implemented in a distributed computing environment, in which one or more of the aforementioned components and functional modules shown in FIG. 1A can be distributed over several local and/or remote devices. By way of example, the examination tools 120 and 121, and the system 101, can be located at the same entity (in some cases hosted by the same device) or distributed over different entities. By way of another example, as described above, in some cases, system 101 can be configured as a training system for training the ML models, while in some other cases, system 101 can be configured as a runtime monitoring system using the trained ML models. The training system and the runtime verification system can be located at the same entity (in some cases hosted by the same device), or distributed over different entities, depending on specific system configurations and implementation needs.

In some examples, certain components utilize a cloud implementation, e.g., are implemented in a private or public cloud. Communication between the various components of the examination system, in cases where they are not located entirely in one location or in one physical entity, can be realized by any signaling system or communication components, modules, protocols, software languages, and drive signals, and can be wired and/or wireless, as appropriate.

It should be further noted that in some embodiments at least some of examination tools 120 and 121, storage unit 122 and/or GUI 124 can be external to the examination system 100 and operate in data communication with systems 100 and 101 via I/O interface 126. System 101 can be implemented as stand-alone computer(s) to be used in conjunction with the examination tools, and/or with the additional examination modules as described above. Alternatively, the respective functions of the system 101 can, at least partly, be integrated with one or more examination tools 120 and 121, thereby facilitating and enhancing the functionalities of the examination tools in examination-related processes.

While not necessarily so, the process of operations of systems 101 and 100 can correspond to some or all of the stages of the methods described with respect to FIGS. 1B-6. Likewise, the methods described with respect to FIGS. 1B-6 and their possible implementations can be implemented by systems 101 and 100. It is therefore noted that embodiments discussed in relation to the methods described with respect to FIGS. 1B-6 can also be implemented, mutatis mutandis, as various embodiments of the systems 101 and 100, and vice versa.

Reference is now made to FIG. 1B, which is a simplified illustration of a process of producing a difference image, also call a Diff image, and assigning attributes to the Diff image according to an example.

FIG. 1B shows input of a current image 132 and a reference image 134, subtracted from one another (136) and producing a Diff image 138. It is noted that the reference image 134 or the current image 132 or both may be computed, synthesized, generated or captured by an imaging device, and one or both of the images may have undergone some processing such as image enhancement or a manipulation of its Signal to Noise Ratio.

The Diff image 138 is analyzed, for example by an automatic analyzer which has been trained by machine learning, and associates images attributes 140 with the Diff image 138, thereby also to the Current image 132 and the defect imaged therein. In some examples the image attributes may be all the attributes 142 associated with the Diff image 138, the Reference image 134 and the Current image 132.

In some examples, additional, non-image attributes such as described above in the section titled “Optionally assigning non-image attributes to a defect” may be associated with the Diff image, and thereby also to the Current image and the defect imaged therein.

It is noted that image and non-image attributes may be assigned, manually or automatically, to the current image 132 and also be assigned to the reference image 134. The process is not shown in FIG. 1B, but can be understood by a person skilled in the art.

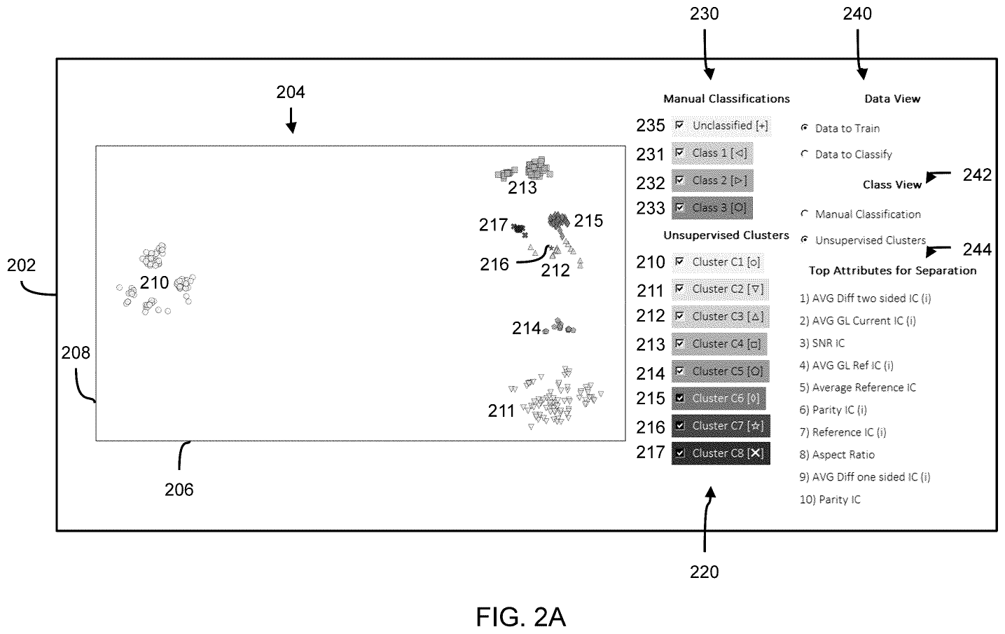

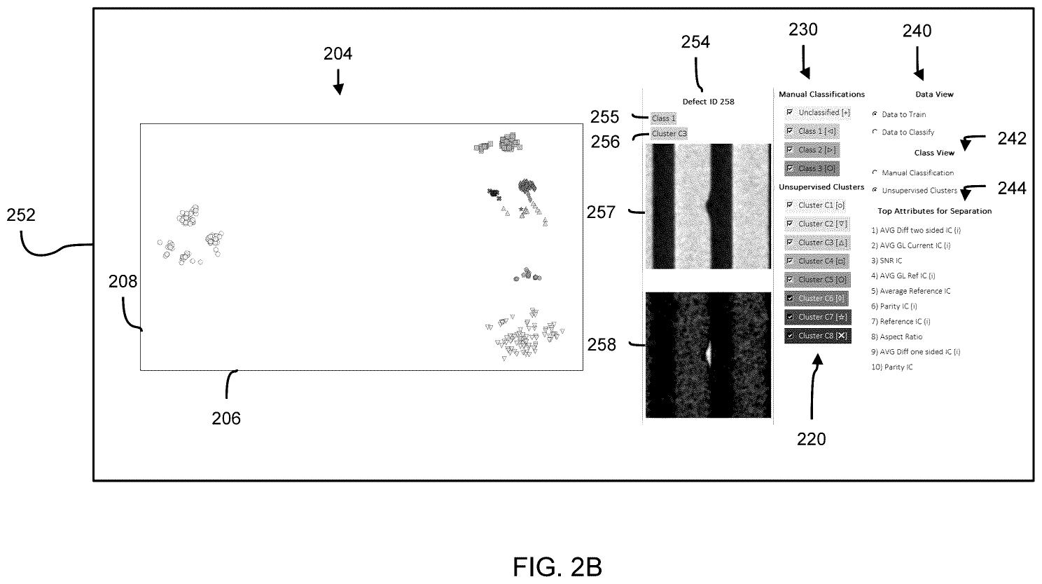

Reference is now made to FIG. 2A, which is a simplified illustration of a user interface according to an example.

FIG. 2A is intended to show an example two-dimensional (2D) scatter plot as described herein.

FIG. 2A shows a user interface 202, with a 2D scatter plot 204. The 2D scatter plot 204 has an X-axis showing values along a first t-SNE axis 206 and a Y-axis showing values along a second t-SNE axis 208. The t-SNE axes are computed on attribute values, either image-based attribute values or non-image-based attribute values.

FIG. 2A shows within the scatter plot 204 markings, each one of which corresponds to one candidate. The scatter plot 204 shows clusters of defects according to their associated values along the first t-SNE axis 206 and the second t-SNE axis 208.

The user interface 202 also includes a legend 220, which indicates what marking 210 211 212 213 214 215 216 217 indicates which cluster 210 211 212 213 214 215 216 217.

FIG. 2A also shows optional additional user interface elements, one or more of which may optionally be displayed together with the 2D scatter plot 204 in the user interface 202:
an optional Data View selection element 240 for selecting whether defect data is to be used for training a defect classifier, or whether the defect data is for using a defect classifier to classify defects. It is noted that a user may toggle between training data and test data, potentially enabling the user to infer differences between the training data and the test data.;
an optional Class View selection element 242 for selecting whether the 2D scatter plot 204 should color-code the defect classes or the unsupervised clusters of the defects, as presently shown in FIG. 2A; and
an optional Top Attributes for Separation field 244 for ranking defect attributes in order of their importance for separating the defects to their given manual classifications. Other names for “Top Attributes for Separation” may be “Feature Importance” or “Significant Features”.

The user interface 202 also includes a legend 230, which may optionally indicate what marking 231 232 233 indicate which defect class is associated with which defect, and which defect is as yet unclassified 235.

It is noted that FIG. 2A does not show color-coding of classified defects, but of unsupervised clusters. The view has been selected to be an Unsupervised cluster view.

Reference is now made to FIG. 2B, which is a simplified illustration of a user interface according to an example.

FIG. 2B is intended to show an example of a 2D scatter plot as described herein and of displaying a defect image and/or a Diff image. The defect image is typically shown after clicking a corresponding location in the 2D scatter plot.

FIG. 2B shows a user interface 252, with a 2D scatter plot 204 similar to the 2D scatter plot 204 shown in FIG. 2A.

The 2D scatter plot 204 has an X-axis showing values along a first t-SNE axis 206 and a Y-axis showing values along a second t-SNE axis 208 similar to FIG. 2A.

FIG. 2B shows within the scatter plot 204 markings, each one of which corresponds to one candidate defect.

The user interface 252 also includes a legend 220, which indicates what marking indicates which cluster, similarly to FIG. 2A.

FIG. 2B also shows optional additional user interface elements, one or more of which may optionally be displayed together with the 2D scatter plot 204 in the user interface 202, similar to FIG. 2A:
an optional Data View selection element 240 for selecting whether defect data is to be used for training a defect classifier, or whether the defect data is for using a defect classifier to classify defects;
an optional Class View selection element 242 for selecting whether the 2D scatter plot 204 should color-code the defect classes or the unsupervised clusters of the defects, as presently shown in FIG. 2B; and
an optional Top Attributes for Separation field 244 for ranking defect attributes in order of their importance for separating the defects to their given manual classifications.

The user interface 202 also includes a legend 230, which may optionally indicate what marking 231 232 233 indicate which defect class is associated with which defect, and which defect is as yet unclassified 235.

It is noted that FIG. 2B does not show classified defects. The view has been selected to be an Unsupervised cluster view.

In addition to user interface elements similar to FIG. 2A, FIG. 2B shows user interface elements for displaying a defect image and/or a Diff image.

FIG. 2B shows optional additional user interface elements, one or more of which may be displayed together with the 2D scatter plot 204 in the user interface 252:
an optional Defect ID field 254 for entering a Defect ID, which may: cause the identified defect marking to be highlighted within the 2D scatter plot 204, or, when a defect in the scatter plot has been selected, display the defect ID;
an optional Class or Category ID field 255 which shows which class or category of defects the defect of the Defect ID field belongs to, if such is already known; and
an optional Cluster ID field 256 which shows which cluster of defects the defect of the Defect ID field belongs to.

It is noted that a defect class or defect category is typically a subjective class to which a user classifies a defect, or an automatic classification class which an automatic classification program selects.

It is noted that a defect cluster is a group of defect candidates which are close to each other based on calculated attributes/characteristics.

We empirically observed that typically there is a correspondence between defect clusters and their subjective defect class/category. In some examples defects belonging to a same cluster may be automatically classified to a same classification

A user may select a specific defect in the 2D scatter plot 204, either by selecting a marking of the defect in the 2D scatter plot 204, or by entering the defect ID in the Defect ID field 254. The user can display a selected defect image 257 in the user interface 252, or display the selected defect Diff image 258, or display both images.

In some examples the defect image 257 may optionally be displayed as an On-The-Fly (OTF) display. An OTF display is named herein as an image where two images are repeatedly displayed one after the other, also called toggled, in a window, geometrically registered to each other, so that a difference between the images, typically a defect, appears to blink on and off. The OTF image assists a human operator to pick out differences between the two images, which assists to pick out a defect. The two images being toggled may be various different image pairings, such as, by way of some non-limiting examples: a Current image and a Reference image; a Current image and a CAD image of the same location; a Current image and a simulation image of the same location; a Diff image and a CAD image of the same location; a Diff image and a reference image of the same location; a Diff image and a simulation image of the same location, and other pairings of images having a same location on a wafer, or a same location relative to a die on the wafer.

Following a display of the selected defect image, the user may classify the defect, by selecting a classification from a drop-down menu of defect classifications which optionally appears (not shown) in the user interface, optionally next to the marking of the selected defect in the scatter plot 204.

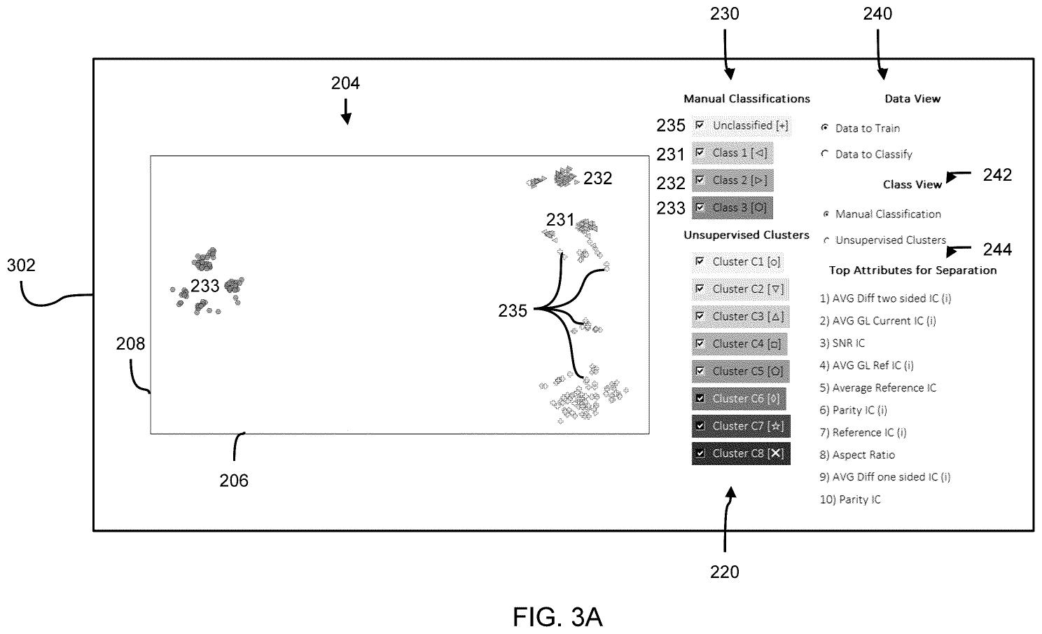

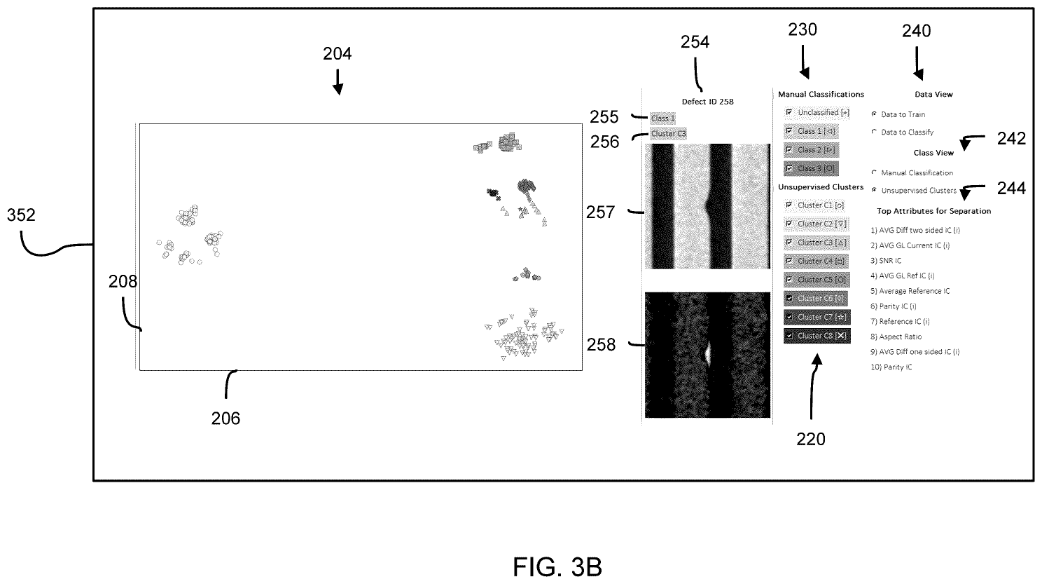

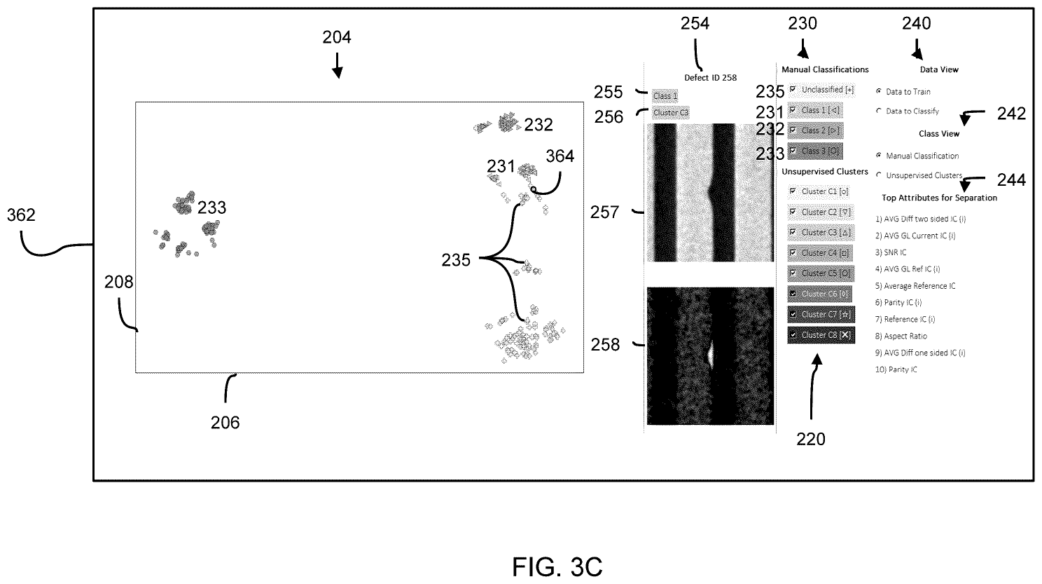

Reference is now made to FIG. 3A, which is a simplified illustration of a user interface according to an example.

FIG. 3A is intended to show an example of a 2D scatter plot as described herein and of displaying classified defects.

FIG. 3A shows a user interface 302, with a 2D scatter plot 204 similar to the 2D scatter plot 204 shown in FIG. 2A.

The 2D scatter plot 204 has an X-axis showing values along a first t-SNE axis 206 and a Y-axis showing values along a second t-SNE axis 208 similar to FIG. 2A.

FIG. 3A shows within the scatter plot 204 markings, each one of which corresponds to one candidate defect.

The user interface 302 also includes a legend 220, which indicates what marking indicates which cluster, similarly to FIG. 2A. in the example case of FIG. 3A, the scatter plot shows defect candidates with color-coding of their defect classifications, based on their attribute values along the first t-SNE axis 206 and the second t-SNE axis 208.

FIG. 3A also shows optional additional user interface elements, one or more of which may optionally be displayed together with the 2D scatter plot 204 in the user interface 302, similar to FIG. 2A:
an optional Data View selection element 240 for selecting whether defect data is to be used for training a defect classifier, or whether the defect data is for using a defect classifier to classify defects;
an optional Class View selection element 242 for selecting whether the 2D scatter plot 204 should show clustering of the data, or classification of the defect data as presently shown in FIG. 3A; and
an optional Top Attributes for Separation field 244 for ranking defect attributes in order of their importance for separating the defects to their given manual classifications.

The user interface 302 also includes a legend 230, which may optionally indicate what class or category 231 232 233 indicate which defect class is associated with which defect, and which defect is as yet unclassified 235.

It is noted that FIG. 3A shows classified defects. The view has been selected to be a Manual Classification view.

A user may select a specific defect in the 2D scatter plot 204, optionally by selecting a marking of the defect in the 2D scatter plot 204. The user can display a selected defect image in the user interface 302, or display a selected defect Diff image, or display both images.

Following a display of the selected defect image, the user may classify the defect, by selecting a classification from a drop-down menu of defect classifications which optionally appears (not shown) in the user interface, optionally next to the marking of the selected defect in the scatter plot 204.

Reference is now made to FIG. 3B, which is a simplified illustration of a user interface according to an example.

FIG. 3B is intended to show an example of a 2D scatter plot as described herein and of displaying a defect image and/or a Diff image.

FIG. 3B shows a user interface 352, with a 2D scatter plot 204 similar to the 2D scatter plot 204 shown in FIG. 2A.

The 2D scatter plot 204 has an X-axis showing values along a first t-SNE axis 206 and a Y-axis showing values along a second t-SNE axis 208 similar to FIG. 2A.

FIG. 3B shows within the scatter plot 204 markings, each one of which corresponds to one candidate defect.

The user interface 352 also includes a legend 220, which indicates what marking indicates which cluster, similarly to FIG. 2A. in the example case of FIG. 3A, the scatter plot shows defect clusters, based on their attribute values along the first t-SNE axis 206 and the second t-SNE axis 208.

FIG. 3B also shows optional additional user interface elements, one or more of which may optionally be displayed together with the 2D scatter plot 204 in the user interface 352, similar to FIG. 2A:
an optional Data View selection element 240 for selecting whether defect data is to be used for training a defect classifier, or whether the defect data is for using a defect classifier to classify defects;
an optional Class View selection element 242 for selecting whether the 2D scatter plot 204 should show clustering of the data, as is presently shown in FIG. 3B, or classification of the defect data as shown in FIG. 3A; and
an optional Top Attributes for Separation field 244 for ranking defect attributes in order of their importance for separating the defects to their given manual classifications.

The user interface 352 also includes a legend 230, which may optionally indicate what class or category indicate which defect class is associated with which defect, and which defect is as yet unclassified.

It is noted that FIG. 3B shows the defect attributes embedding view with color-coding corresponding to their unsupervised clusters. The view has been selected to be an Unsupervised Clusters view, that is, the clustering has been performed by an unsupervised clustering method.

FIG. 3B shows optional additional user interface elements, one or more of which may be displayed together with the 2D scatter plot 204 in the user interface 352:
an optional Defect ID field 254 for entering a Defect ID, which may: cause the identified defect marking to be highlighted within the 2D scatter plot 204, or, when a defect in the scatter plot has been selected, display the defect ID;
an optional Class or Category ID field 255 which shows which class or category of defects the defect of the Defect ID field belongs to, if such is already known; and
an optional Cluster ID field 256 which shows which cluster of defects the defect of the Defect ID field belongs to.

A user may select a specific defect in the 2D scatter plot 204, optionally by selecting a marking of the defect in the 2D scatter plot 204, or by entering a defect ID into the Defect ID field 254. The user can display a selected defect image in the user interface 302, or display a selected defect Diff image, or display both images.

Following a display of the selected defect image, the user may classify the defect, by selecting a classification from a drop-down menu of defect classifications which optionally appears (not shown) in the user interface, optionally next to the marking of the selected defect in the scatter plot 204.

Reference is now made to FIG. 3C, which is a simplified illustration of a user interface according to an example.

FIG. 3C is intended to show an example of a 2D scatter plot as described herein and of displaying classified defects.

FIG. 3C shows a user interface 362, with a 2D scatter plot 204 similar to the 2D scatter plot 204 shown in FIG. 2A.

The 2D scatter plot 204 has an X-axis showing values along a first t-SNE axis 206 and a Y-axis showing values along a second t-SNE axis 208 similar to FIG. 2A.

FIG. 3C shows within the scatter plot 204 markings, each one of which corresponds to one candidate defect.

The user interface 362 also includes a legend 220, which indicates what marking indicates which cluster, similarly to FIG. 2A. In the example case of FIG. 3C, the scatter plot shows defect classifications, based on their attribute values along the first t-SNE axis 206 and the second t-SNE axis 208.

FIG. 3C also shows optional additional user interface elements, one or more of which may optionally be displayed together with the 2D scatter plot 204 in the user interface 362, similar to FIG. 2A:
an optional Data View selection element 240 for selecting whether defect data is to be used for training a defect classifier, or whether the defect data is for using a defect classifier to classify defects;
an optional Class View selection element 242 for selecting whether the 2D scatter plot 204 should show clustering of the data, or classification of the defect data as presently shown in FIG. 3C; and
an optional Top Attributes for Separation field 244 for ranking defect attributes in order of their importance for separating the defects to their given manual classifications.

The user interface 362 also includes a legend 230, which may optionally indicate what class or category 231 232 233 indicate which defect class is associated with which defect, and which defect is as yet unclassified 235.

It is noted that FIG. 3C shows classified defects. The view has been selected to be a Manual Classification view, that is, the classification has been performed manually, by a user. In some examples, one or more representative defects have been manually classified by a user, and other defects of a same cluster are optionally classified similarly to the classification of the manually classified defects. By way of a non-limiting example, in some cases a user may select a group of defects in the scatter plot 204 using a mouse and classify the group. In some cases, the user may instruct the user interface 362 to classify a cluster of defects as a specific class or category.

We empirically observed that typically there is a correspondence between defect clusters and their subjective defect class/category. In some examples defects belonging to a same cluster may be automatically classified to a same classification

A user may select a specific defect 364 in the 2D scatter plot 204, optionally by selecting a marking of the defect in the 2D scatter plot 204. The user can display a selected defect 364 image in the user interface 362, or display a selected defect 364 Diff image, or display both images.

Following a display of the selected defect 364 image, the user may classify the defect, by selecting a classification from a drop-down menu of defect classifications which optionally appears (not shown) in the user interface, optionally next to the marking of the selected defect 364 in the scatter plot 204.

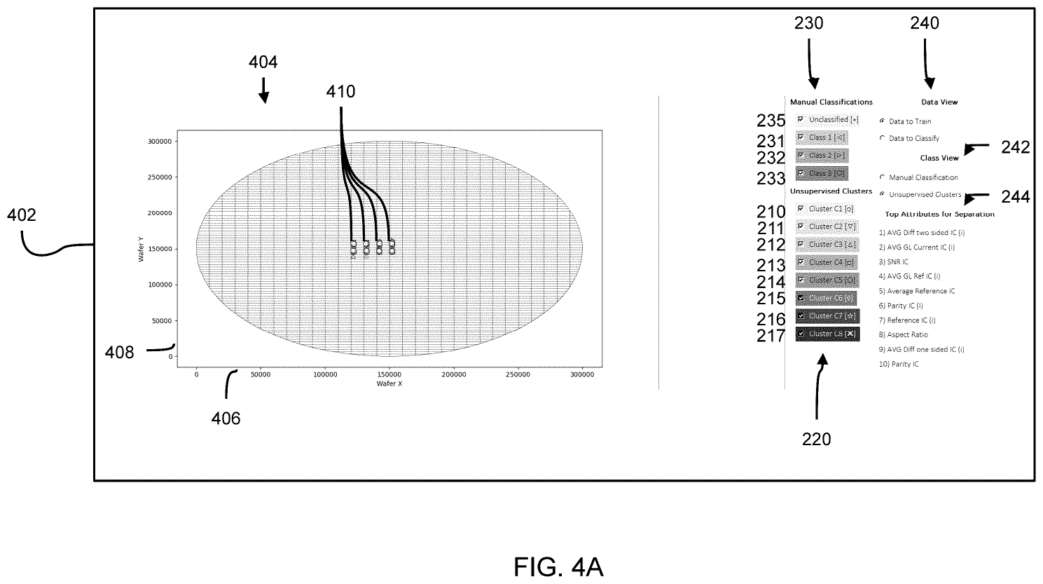

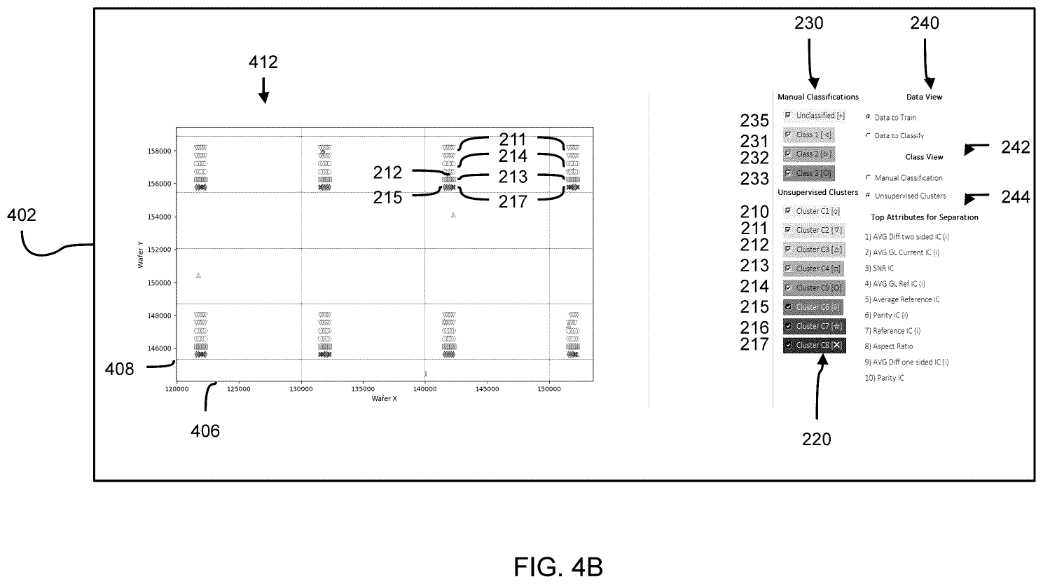

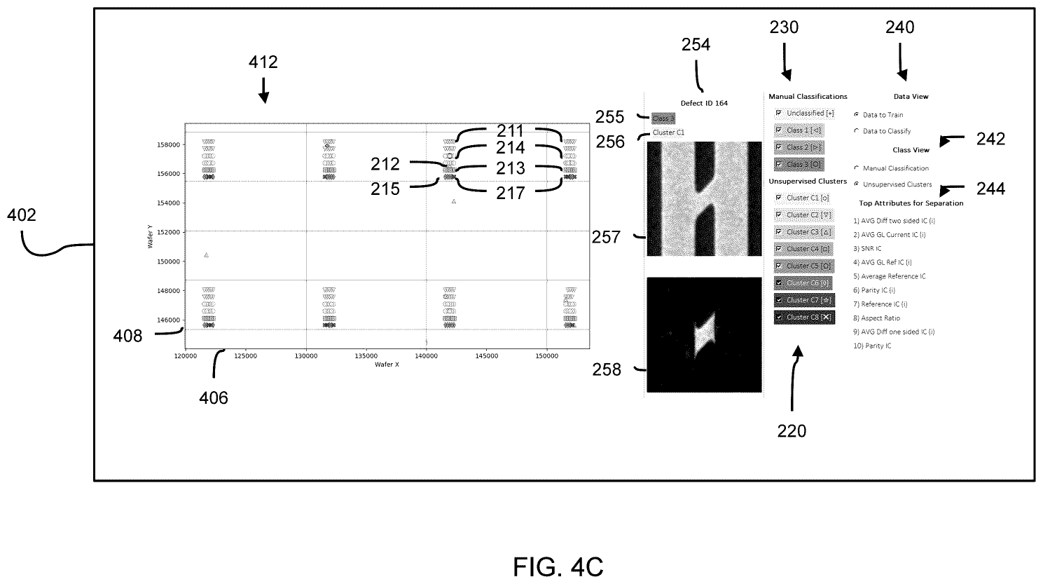

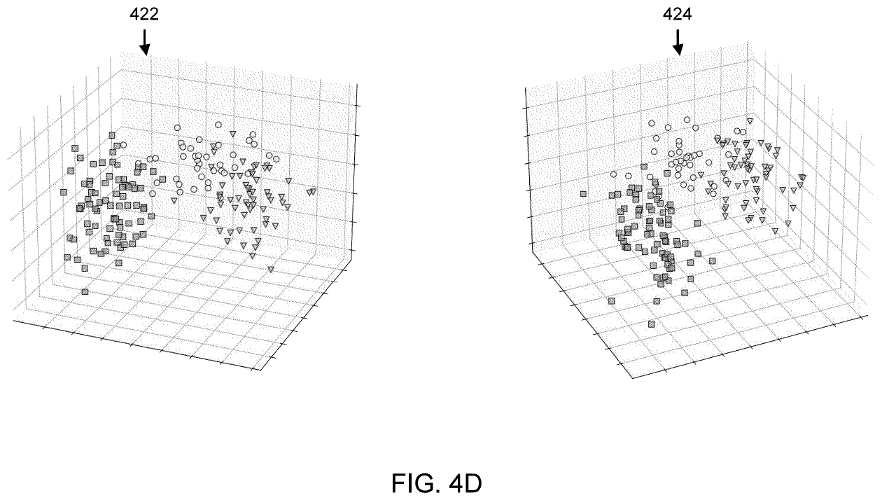

Reference is now made to FIG. 4A, which is a simplified illustration of a user interface according to an example.

FIG. 4A is intended to show an example of a 2D mapping of defects.

FIG. 4A shows a user interface 402, with a 2D map of defects 404.

The 2D map 204 has an X-axis 406 corresponding to a first direction along a semiconductor wafer under inspection, having units of length, and a Y-axis 408 along a second, perpendicular direction along the semiconductor wafer.

FIG. 4A shows within the wafer map markings 410, each one of which corresponds to one candidate defect.

The user interface 402 also includes a legend 220, which indicates what marking indicates which defect cluster 210 211 212 213 214 215 216 217, clustered by an algorithm on a high dimensional attribute space, such as K-Means++, using t-SNE axes or some other embedding algorithm for visualization, as described elsewhere herein.

FIG. 4A also shows optional additional user interface elements, one or more of which may optionally be displayed together with the 2D map of defects 404 in the user interface 402:
an optional Data View selection element 240 for selecting whether defect data is to be used for training a defect classifier, or whether the defect data is for using a defect classifier to classify defects;
an optional Class View selection element 242 for selecting whether the 2D map of defects 404 shows unsupervised clustering of the data, as is presently shown in FIG. 4A, or classification of the defect data; and
an optional Top Attributes for Separation field 244 for ranking defect attributes in order of their importance for separating the defects to their given manual classifications.

The user interface 402 also includes a legend 230, which may optionally indicate what class or category 231 232 233 indicate which defect class is associated with which defect, and which defect is as yet unclassified 235.

It is noted that FIG. 4A shows defects in a small area of the wafer. The small area is an area which has been inspected and where defect candidates have been discovered. In some cases, an entire wafer can be scanned and some or all of the defect candidates may be displayed.

In some examples the 2D map of defects 404 may include data from several wafers, registered to a same coordinate system, so that defects from multiple wafers can be displayed and analyzed together.

Reference is now made to FIG. 4B, which is a simplified illustration of a user interface according to an example.

FIG. 4B is intended to show an example of an enlarged 2D mapping of defects.

FIG. 4B shows a user interface 402, showing an enlarged portion 412 of the 2D map of defects 404 shown in FIG. 4A.

The enlarged portion 412 has an X-axis 406 corresponding to a first direction along a semiconductor wafer under inspection, having units of length, and a Y-axis 408 along a second, perpendicular direction along the semiconductor wafer.

FIG. 4B shows within the enlarged portion 412 markings, each one of which corresponds to one candidate defect.

In some examples the enlarged portion 412 may include data from several wafers, registered to a same coordinate system, so that defects from multiple wafers can be displayed and analyzed together.

In some examples the enlarged portion 412 may include data from a specific die on a wafer, from several wafers, registered to a same coordinate system, so that defects from multiple wafers can be displayed and analyzed together. Such display potentially enables to detect and analyze location-dependent defect at a die level.

The user interface 402 also includes a legend 220, which indicates what marking 210 211 212 213 214 215 216 217 indicates which defect cluster, clustered according to t-SNE axes as described elsewhere herein. In the enlarged portion 412 a point represents a defect candidate, and color coding indicates which defect cluster the defect belongs to.

FIG. 4B also shows optional additional user interface elements, one or more of which may optionally be displayed together with the enlarged portion 412:
an optional Data View selection element 240 for selecting whether defect data is to be used for training a defect classifier, or whether the defect data is for using a defect classifier to classify defects;
an optional Class View selection element 242 for selecting whether the enlarged portion 412 shows color-coding of unsupervised clustering of the defect data, as is presently shown in FIG. 4B, or of manual classification of the defect data; and
an optional Top Attributes for Separation field 244 for ranking defect attributes in order of their importance for separating the defects to their given manual classifications.

The user interface 402 also includes a legend 230, which may optionally indicate what class or category 231 232 233 indicate which defect class is associated with which defect, and which defect is as yet unclassified 235.

It is noted that FIG. 4B shows an enlarged view of defects in a small area of the wafer. The enlarged view enables viewing separate candidate defect locations.

FIG. 4B shows where on a wafer specific defect clusters 211 212 213 214 215 217 as defined by the t-SNE axes described herein are located.

Reference is now made to FIG. 4C, which is a simplified illustration of a user interface according to an example.

FIG. 4C is intended to show an example of an enlarged 2D mapping of defects, and of displaying a defect image and/or a Diff image.

FIG. 4C shows a user interface 402, showing an enlarged portion 412 of the 2D map of defects 404 shown in FIG. 4A.

The enlarged portion 412 has an X-axis 406 corresponding to a first direction along a semiconductor wafer under inspection, having units of length, and a Y-axis 408 along a second, perpendicular direction along the semiconductor wafer.

FIG. 4C shows within the enlarged portion 412 markings, each one of which corresponds to one candidate defect.

The user interface 402 also includes a legend 220, which indicates what marking indicates which defect cluster, clustered by an algorithm on a high dimensional attribute space, such as K-Means++, using t-SNE axes or some other embedding algorithm for visualization, as described elsewhere herein.

FIG. 4C also shows optional additional user interface elements, one or more of which may optionally be displayed together with the enlarged portion 412:
an optional Defect ID field 254 for entering a Defect ID, which may: cause the identified defect marking to be highlighted within the enlarged portion 412, or, when a defect in the enlarged portion 412 has been selected, display the defect ID;
an optional Class or Category ID field 255 which shows which class or category of defects the defect of the Defect ID field belongs to, if such is already known; and
an optional Cluster ID field 256 which shows which cluster of defects the defect of the Defect ID field belongs to;
an optional Data View selection element 240 for selecting whether defect data is to be used for training a defect classifier, or whether the defect data is for using a defect classifier to classify defects;
an optional Class View selection element 242 for selecting whether the enlarged portion 412 shows unsupervised clustering of the data, as is presently shown in FIG. 4C, or classification of the defect data; and
an optional Top Attributes for Separation field 244 for ranking defect attributes in order of their importance for separating the defects to their given manual classifications.

The user interface 402 also includes a legend 230, which may optionally indicate what class or category indicate which defect class is associated with which defect, and which defect is as yet unclassified.

It is noted that FIG. 4C shows an enlarged view of defects in a small area of the wafer. The enlarged view enables viewing separate candidate defect locations.

FIG. 4C shows where on a wafer specific defect clusters 211 212 213 214 215 217 as defined by the t-SNE axes described herein are located.

A user may select a specific defect in the enlarged portion 412, either by selecting a marking of the defect in the enlarged portion 412 of the defect map, or by entering the defect ID in a Defect ID field 254. The user can optionally display a selected defect image 257 in the user interface 252, or display the selected defect Diff image 258, or display both images.

Reference is now made to FIG. 4D, which is a simplified illustration of three-dimensional (3D) scatter plots according to an example.

The drawings of the user interface described herein are mostly presented with examples of a 2D scatter plot. In order to show that the user interface described herein may optionally use a 3D scatter plot, FIG. 4D shows two 3D scatter plots 422 424. The two 3D scatter plot show a same 3D scatter plot, as viewed from two different points of view in relation to a same volume and same scatter plot.

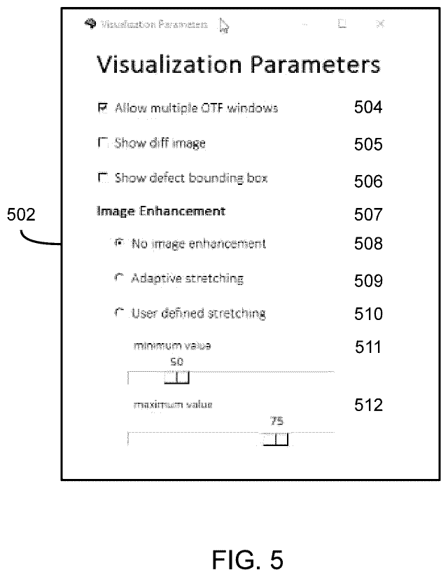

Reference is now made to FIG. 5, which is a simplified illustration of a user interface element according to an example.

FIG. 5 shows a non-limiting example of selectable actions provided when activating the above-mentioned Visualization Parameters user interface element.

In some examples, when the above-mentioned Visualization Parameters user interface element is activated, a window 502 is opened, within which various image visualization options are presented to a user, and the user may select some or even all the visualization options.

Some non-limiting examples of visualization options are shown in FIG. 5:
(504) enabling display of multiple On The Fly (OTF) windows to be displayed.
(505) displaying a Diff image.
(506) showing a candidate defect bounding box. The candidate defect bounding box is typically automatically detected by image processing of a Current image and a Reference image, or image processing of the Diff image.
(507) providing various image enhancement options such as, by way of some non-limiting examples:
(508) providing no image enhancement.
(509) providing adaptive image enhancement.
(510) providing user defined image enhancement between a minimum value (511) and a maximum value (512) which is applicable to the image enhancement, the maximum and minimum parameter values being defined by a user, optionally by using a slider user interface element.

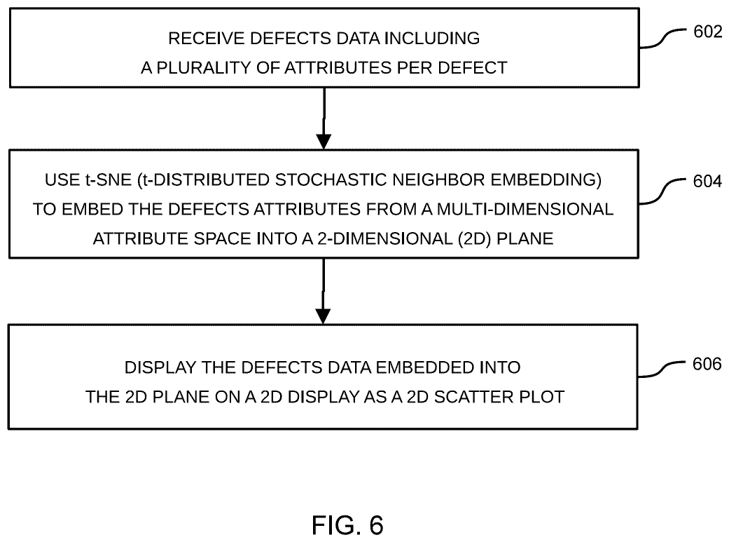

Reference is now made to FIG. 6, which is a simplified flow chart illustration of a method of presenting defects data produced by inspection of wafers or masks according to an example.

The method of FIG. 4 includes:
(a) receiving defects data including a plurality of attributes per defect (602);
(b) using t-SNE (t-distributed Stochastic Neighbor Embedding) to embed the defects attributes from a multi-dimensional attribute space into a 2-dimensional (2D) plane (604); and
(c) displaying the defects data embedded into the 2D plane on a 2D display as a 2D scatter plot (606).

### Non-Limiting Examples of Use of the User Interface

In some examples, the user interface described herein is used to classify defect images in a specific defect image population, to provide feedback, for example a report, on how many defects of each type exist in the specific population of defects.

In some examples, the user interface described herein is used to classify defect images in a specific defect image population, and to export the defect image population for use in training a machine-learning classifier to classify defects.

In some examples, the user interface described herein is used by selecting one attribute to be a processing system or machine ID, to compare defect production numbers and classifications between system or machine IDs.

In some examples, the user interface described herein is used by selecting one attribute to be an attribute such as a time of manufacture, to compare defect production numbers and classifications between times produced, potentially enabling to correct specific operators, work shifts, and so on.

In some examples, the user interface is used for defect characterization in a Research and Development environment, where wafers may include an unusually large number of defects, and a tool for rapidly assessing defect classes can potentially reduce duration of defect characterization and/or identification of defect sources.

In some examples, the user interface described herein is used by selecting one or more attributes to be an attribute such as a manufacturing parameter used in manufacturing of a wafer. Such parameters include, by way of some non-limiting examples, exposure duration of photoresist, development parameters related to developing photoresist, etch duration, etch energy, and additional production parameters used in production of semiconductor circuits on semiconductor wafers. Such attributes potentially enable to identify relations of defects to the production parameters.

In some examples, the user interface is optionally used to provide rapid defect characterization in a wafer manufacturing development process, to close a feedback loop and evaluate defect levels of different experimental processes or changes to established processes.

### SUMMARY OF THE PRESENT DISCLOSURE

### Example 1

A method of presenting defects data produced by inspection of semiconductor wafers or masks, the method including:
(a) receiving defects data including a plurality of attributes per defect,
(b) using t-SNE (t-distributed Stochastic Neighbor Embedding) to embed the defects attributes from a multi-dimensional attribute space into a lower-dimension space, and
(c) displaying the defect data embedded into the lower-dimension space on a 2D display as a scatter plot.

### Example 2

The method according to example 1 and further including
(d) adding image or non-image attributes to at least one defect and
(e) performing steps (b) and (c) again.

### Example 3

The method according to any one of examples 1-2 wherein the attributes include attributes produced by input of a defect image to an image processing module trained to produce the attributes based on the defect image.

### Example 4

The method according to any one of examples 1-3 wherein the attributes include attributes produced by input of a defect image to a machine learning module trained to produce the attributes based on the defect image.

### Example 5

The method according to any one of examples 1-4 wherein the lower-dimension space is a 2-dimensional (2D) plane and the user interface displays a 2D scatter plot.

### Example 6

The method according to any one of examples 1-4 wherein the lower-dimension space is a 3-dimensional (3D) volume and the user interface displays a three-dimensional (3D) scatter plot.

### Example 7

The method according to any one of examples 1-5 wherein the user interface displays two 2D scatter plots, wherein the defects have been classified into categories, a first 2D scatter plot displays defects which have been classified manually, and a second 2D scatter plot displays defects which have been classified by automatic classification.

### Example 8

The method according to any one of examples 1-7 wherein the user interface enables a user to select one defect in one of the 2D scatter plots and display an image of the defect.

### Example 9

The method according to example 8 wherein the defect image includes a digital image obtained from an e-beam inspection machine.

### Example 10

The method according to example 8 wherein the defect image includes a digital image obtained from an optical inspection machine.

### Example 11

The method according to any one of examples 8-10 wherein the display of the image of the defect is by displaying one image of the defect and one image of a same area without the defect, to cause appearance of the defect to switch on and off.

### Example 12

The method according to any one of examples 1-11 wherein the user interface enables selecting which method is used, instead of t-SNE, to reduce dimensionality of the plurality of attributes to the number of axes of the scatter plot(s).

### Example 13

The method according to example 7 wherein the user interface enables to select one defect in the second 2D scatter plot which displays defects which have been classified by automatic classification and classify the defect manually.

### Example 14

The method according to example 7 wherein the user interface enables to select one defect in the second 2D scatter plot which displays defects which have been classified by manual classification and submit the defect to automatic classification.

### Example 15

The method according to any one of examples 1-14 wherein the attributes of the axes of the scatter plot(s) include processing data including one or more of identity of a machine which produced the defect, date upon which the defect was produced, time upon which the defect was produced, location of the defect on a die, location of the defect on a wafer, location of the defect on a mask, identity of an inspection machine, and identity of operator of the inspection machine.

### Example 16

A non-transitory computer-readable medium storing instructions that, when executed by a processor, cause the processor to perform operations including:
(a) receiving defects data including a plurality of attributes per defect,
(b) using t-SNE (t-distributed Stochastic Neighbor Embedding) to embed the defects attributes from a multi-dimensional attribute space into a lower-dimension space, and
(c) displaying the defect data embedded into the lower-dimension space on a 2D display as a scatter plot.

### Example 17

A system for inspecting wafers or masks, the system including a user interface for presenting defect data produced by inspection of wafers or masks, the user interface implementing a method including:
(a) receiving defects data including a plurality of attributes per defect,
(b) using t-SNE (t-distributed Stochastic Neighbor Embedding) to embed the defects attributes from a multi-dimensional attribute space into a lower-dimension space, and
(c) displaying the defect data embedded into the lower-dimension space on a 2D display as a scatter plot.

### Example 18

The system according to example 17 and further including a database for storing defect images and defect image attributes associated with the defect images.

### Example 19

The system according to any one of examples 17-18 and further including a database for storing non-image attributes associated with the defect images.

As such, those skilled in the art to which the present invention pertains, can appreciate that while the present invention has been described in terms of preferred examples, the concept upon which this disclosure is based may readily be utilized as a basis for the designing of other structures, systems and processes for carrying out the several purposes of the present invention.

The various illustrative logical blocks, modules, and algorithm steps described in connection with the examples disclosed herein can be implemented as electronic hardware, computer software, or combinations of both. To clearly illustrate this interchangeability of hardware and software, various illustrative components, blocks, modules, and steps have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing any departure from the scope of the disclosure.

It will also be understood that the system according to the present disclosure may be, at least partly, implemented on a suitably programmed computer. Likewise, the present disclosure contemplates a computer program being readable by a computer for executing the method of the invention. The present disclosure further contemplates a non-transitory computer-readable memory tangibly embodying a program of instructions executable by the computer for executing the method of the present disclosure.

Also, it is to be understood that the phraseology and terminology employed herein are for the purpose of description and should not be regarded as limiting.

It should be noted that the words “comprising”, “including” and “having” as used throughout the appended claims are to be interpreted to mean “including but not limited to”. The indefinite articles “a” and “an,” as used herein in the specification and in the claims, unless clearly indicated to the contrary, should be understood to mean “at least one.” The phrase “and/or,” as used herein in the specification and in the claims, should be understood to mean “either or both” of the elements so conjoined, i.e., elements that are conjunctively present in some cases, and disjunctively present in other cases.

It is important, therefore, that the scope of the invention is not construed as being limited by the illustrative examples set forth herein. Other variations are possible within the scope of the present invention as defined in the appended claims. Other combinations and sub-combinations of features, functions, elements and/or properties may be claimed through amendment of the present claims or presentation of new claims in this or a related application. Such amended or new claims, whether they are directed to different combinations or directed to the same combinations, whether different, broader, narrower or equal in scope to the original claims, are also regarded as included within the subject matter of the present description.

It is expected that during the life of a patent maturing from this application many relevant wafer or mask inspection systems will be developed and the scope of the term wafer or mask inspection system is intended to include all such new technologies a priori.

The terms “comprising”, “including”, “having” and their conjugates mean “including but not limited to”.

The term “consisting of” is intended to mean “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a unit” or “at least one unit” may include a plurality of units, including combinations thereof.

The words “example” and “exemplary” are used herein to mean “serving as an example, instance or illustration”. Any embodiment described as an “example or “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the disclosure may include a plurality of “optional” features unless such features conflict.

Unless otherwise indicated, numbers used herein and any number ranges based thereon are approximations within the accuracy of reasonable measurement and rounding errors as understood by persons skilled in the art

It is appreciated that certain features of the disclosure, which are, for clarity, described in the context of separate embodiments, may also be provided in combination in a single embodiment. Conversely, various features of the disclosure, which are, for brevity, described in the context of a single embodiment, may also be provided separately or in any suitable sub-combination or as suitable in any other described embodiment of the disclosure. Certain features described in the context of various embodiments are not to be considered essential features of those embodiments, unless the embodiment is inoperative without those elements.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

What is claimed is:

1. A method of presenting defects data produced by inspection of semiconductor wafers or masks, the method comprising:
(a) receiving defects data comprising a plurality of attributes per defect;
(b) using t-SNE (t-distributed Stochastic Neighbor Embedding) to embed the defects attributes from a multi-dimensional attribute space into a lower-dimension space; and
(c) displaying the defect data embedded into the lower-dimension space on a 2D display as a scatter plot.

2. The method according to claim 1 and further comprising:
(d) adding image or non-image attributes to at least one defect; and
(e) performing steps (b) and (c) again.

3. The method according to claim 1 wherein the attributes comprise attributes produced by input of a defect image to an image processing module trained to produce the attributes based on the defect image.

4. The method according to claim 1 wherein the attributes comprise attributes produced by input of a defect image to a machine learning module trained to produce the attributes based on the defect image.

5. The method according to claim 1 wherein the lower-dimension space is a 2-dimensional (2D) plane and the user interface displays a 2D scatter plot.

6. The method according to claim 1 wherein the lower-dimension space is a 3-dimensional (3D) volume and the user interface displays a three-dimensional (3D) scatter plot.

7. The method according to claim 1 wherein the user interface displays two 2D scatter plots,
wherein:
the defects have been classified into categories;
a first 2D scatter plot displays defects which have been classified manually; and
a second 2D scatter plot displays defects which have been classified by automatic classification.

8. The method according to claim 1 wherein the user interface enables a user to select one defect in one of the 2D scatter plots and display an image of the defect.

9. The method according to claim 8 wherein the defect image comprises a digital image obtained from an e-beam inspection machine.

10. The method according to claim 8 wherein the defect image comprises a digital image obtained from an optical inspection machine.

11. The method according to claim 8 wherein the display of the image of the defect is by displaying one image of the defect and one image of a same area without the defect, to cause appearance of the defect to switch on and off.

12. The method according to claim 1 wherein the user interface enables selecting which method is used, instead of t-SNE, to reduce dimensionality of the plurality of attributes to the number of axes of the scatter plot(s).

13. The method according to claim 7 wherein the user interface enables to select one defect in the second 2D scatter plot which displays defects which have been classified by automatic classification and classify the defect manually.

14. The method according to claim 7 wherein the user interface enables to select one defect in the second 2D scatter plot which displays defects which have been classified by manual classification and submit the defect to automatic classification.

15. The method according to claim 1 wherein the attributes of the axes of the scatter plot(s) include processing data comprising one or more of:
identity of a machine which produced the defect;
date upon which the defect was produced;
time upon which the defect was produced;
location of the defect on a die;
location of the defect on a wafer;
location of the defect on a mask;
identity of an inspection machine; and
identity of operator of the inspection machine.

16. A non-transitory computer-readable medium storing instructions that, when executed by a processor, cause the processor to perform operations comprising:
(a) receiving defects data comprising a plurality of attributes per defect;
(b) using t-SNE (t-distributed Stochastic Neighbor Embedding) to embed the defects attributes from a multi-dimensional attribute space into a lower-dimension space; and
(c) displaying the defect data embedded into the lower-dimension space on a 2D display as a scatter plot.

17. A system for inspecting wafers or masks, the system comprising a user interface for presenting defect data produced by inspection of wafers or masks, the user interface implementing a method comprising:
(a) receiving defect data comprising a plurality of attributes per defect;
(b) using t-SNE (t-distributed Stochastic Neighbor Embedding) to embed the defects attributes from a multi-dimensional attribute space into a lower-dimension space; and
(c) displaying the defects data embedded into the lower-dimension space on a 2D display as a scatter plot.

18. The system according to claim 17 and further comprising a database for storing defect images and defect image attributes associated with the defect images.

19. The system according to claim 17 and further comprising a database for storing non-image attributes associated with the defect images.
